(19) United States
(12) Patent Application Publication
(10) Pub. No.: US 2025/0034711 A1
(43) Pub. Date: Jan. 30, 2025

(54) SUBSTRATE PROCESSING APPARATUS AND METHOD OF DISPOSING SUBSTRATE

(71) Applicant: Tokyo Electron Limited, Tokyo (JP)

(72) Inventors: Gaku WATANABE, Kumamoto (JP); Morihito INAGAKI, Yamanashi (JP)

(21) Appl. No.: 18/778,472

(22) Filed: Jul. 19, 2024

(30) Foreign Application Priority Data
Jul. 25, 2023 (JP) 2023-120426

(51) Int. Cl. C23C 16/458; C23C 16/455; C23C 16/52

(52) U.S. Cl. CPC C23C 16/4584; C23C 16/45544; C23C 16/52

(57) ABSTRACT

A substrate processing apparatus includes a processing container, a rotary table, a stage, an imaging device, and a controller. The rotary table includes a rotary table side marker capable of being positioned within an imaging range of the imaging device. The stage includes a stage side marker capable of being positioned within the imaging range of the imaging device. The controller recognizes a circumferential position of the rotary table based on the rotary table side marker included in the imaging information, and corrects a position of the rotary table when the rotary table side marker is misaligned. Further, the controller recognizes a circumferential position of the stage based on the stage side marker included in the imaging information, and corrects a position of the stage when the stage side marker is misaligned.

### CROSS-REFERENCE TO RELATED APPLICATIONS

This application is based on and claims priority from Japanese Patent Application No. 2023-120426, filed on Jul. 25, 2023, with the Japan Patent Office, the disclosure of which is incorporated herein in its entirety by reference.

### TECHNICAL FIELD

The present disclosure relates to a substrate processing apparatus and a method of disposing a substrate.

### BACKGROUND

Japanese Patent Laid-Open Publication No. 2014-123673 discloses a substrate processing apparatus that disposes substrates respectively in a plurality of recesses of a rotary table, which serves as a susceptor, to perform a substrate processing such as film formation processing. The substrate processing apparatus is equipped with a camera in a processing container, which captures images of a susceptor mark of the rotary table (rotary table side marker). The substrate processing apparatus corrects positions of the recesses of the rotary table based on the imaging information of the susceptor mark, and transfers the substrates to the corrected positions of the recesses.

Further, in recent years, a substrate processing apparatus has been developed in which a stage with a recess for disposing a substrate is rotatable (in-place rotation) relative to a rotary table that rotates (revolves) in a processing container. When a substrate is disposed on each stage in the substrate processing apparatus, it becomes necessary to determine the position of each stage, in addition to determining the position of the rotary table.

### SUMMARY

According to one aspect of the present disclosure, there is provided a substrate processing apparatus including a processing container, a rotary table rotatably provided in the processing container, a stage having a rotation center positioned away from a rotation center of the rotary table, the stage being rotatable relative to the rotary table, an imaging device provided in the processing container and configured to capture an image of the rotary table and the stage, and a controller configured to process imaging information from the imaging device and to control rotation of the rotary table and operation of the stage. The rotary table includes a rotary table side marker capable of being positioned within an imaging range of the imaging device by rotation of the rotary table. The stage includes a stage side marker capable of being positioned within the imaging range of the imaging device by rotation of the stage. The controller is configured to recognize a circumferential position of the rotary table based on the rotary table side marker included in the imaging information, and correct a position of the rotary table when the rotary table side marker is misaligned, and to recognize a circumferential position of the stage based on the stage side marker included in the imaging information, and correct a position of the stage when the stage side marker is misaligned.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a longitudinal cross-sectional view illustrating a configuration example of a substrate processing apparatus 1 according to an embodiment.

FIG. 2 is a plan view illustrating a configuration inside a processing container of the substrate processing apparatus of FIG. 1.

FIG. 3 is a perspective view illustrating a configuration of a rotary table and a stage of the substrate processing apparatus of FIG. 1.

FIG. 4 is a side view schematically illustrating the installation state of an imaging device in the processing container.

FIG. 5A is a plan view illustrating a first example of imaging information captured by the imaging device. FIG. 5B is a plan view illustrating a second example of imaging information captured by the imaging device.

FIG. 6A is a first explanatory diagram illustrating an example in which two stage side markers are captured by clockwise rotation. FIG. 6B is a second explanatory diagram illustrating an example in which two stage side markers are captured by clockwise rotation and counterclockwise rotation.

FIG. 7 is a first flowchart illustrating the correction of a rotary table position and the correction of a stage position.

FIG. 8 is a second flowchart illustrating the correction of a rotary table position and the correction of a stage position.

### DETAILED DESCRIPTION

In the following detailed description, reference is made to the accompanying drawings, which form a part thereof. The illustrative embodiments described in the detailed description, drawings, and claims are not meant to be limiting. Other embodiments may be utilized, and other changes may be made without departing from the spirit or scope of the subject matter presented here.

Hereinafter, embodiments for carrying out the present disclosure will be described with reference to the drawings. In each drawing, the same reference numerals may be given to the same components, and redundant descriptions may be omitted.

[Configuration of Substrate Processing Apparatus]

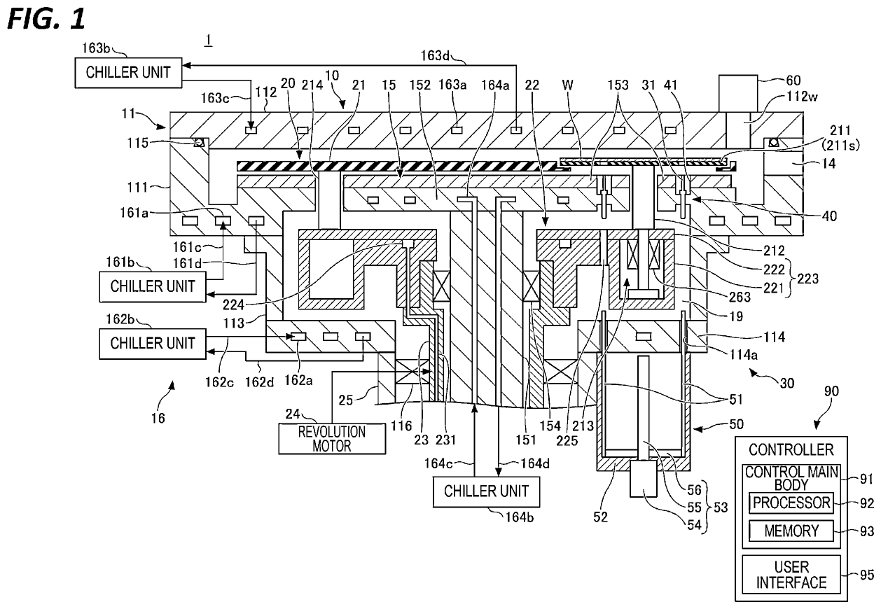

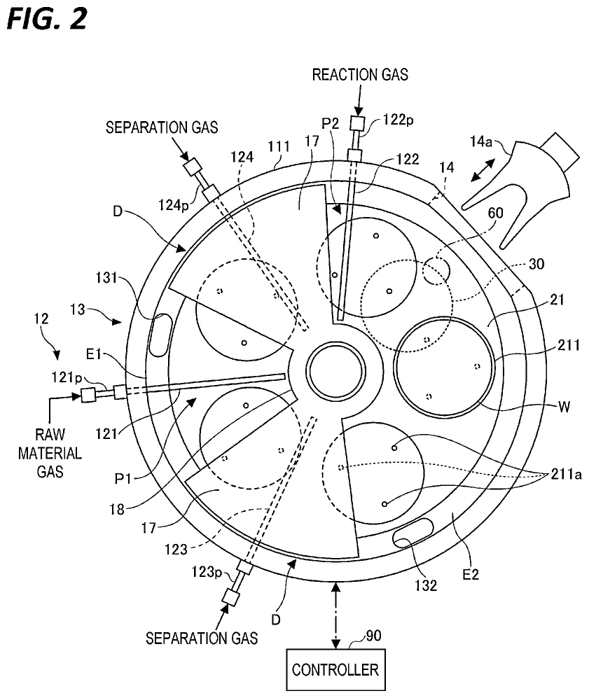

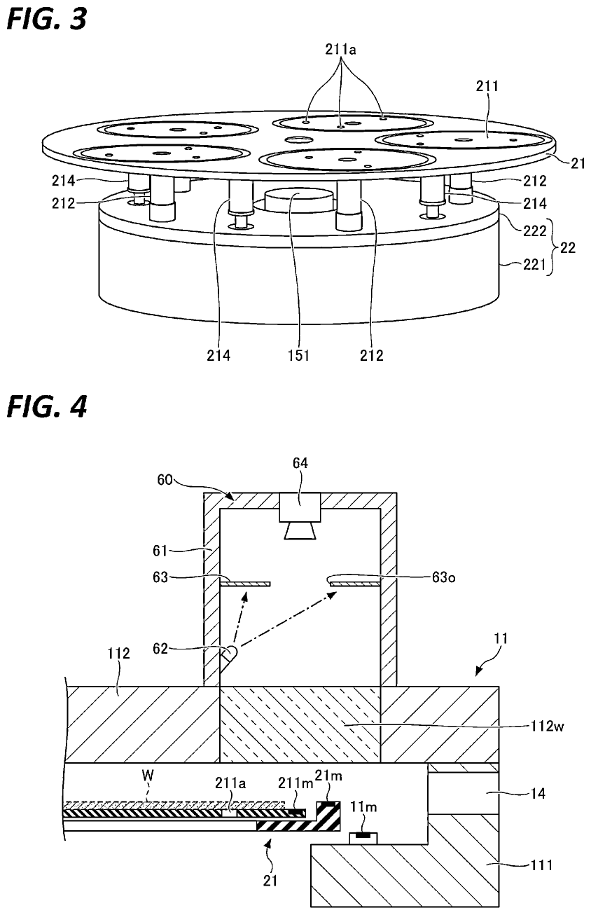

A substrate processing apparatus 1 according to an embodiment will be described with reference to FIGS. 1 to 3. FIG. 1 is a longitudinal cross-sectional view illustrating a configuration example of the substrate processing apparatus 1 according to an embodiment. FIG. 2 is a plan view illustrating a configuration inside a processing container 11 of the substrate processing apparatus 1 of FIG. 1. In FIG. 2, for the convenience of description, the illustration of a top plate is omitted. FIG. 3 is a perspective view illustrating a configuration of a rotary table 21 and a stage 211 of the substrate processing apparatus 1 of FIG. 1.

The substrate processing apparatus 1 is configured to perform a film formation processing for forming a film on a surface of a substrate W by an atomic layer deposition (ALD) or molecular layer deposition (MLD) method. The substrate processing apparatus 1 includes a processing section 10, a rotational drive device 20, a lifter 30, and a controller 90.

The processing section 10 executes a film formation processing to form a film on the substrate W. The processing section 10 includes the processing container 11, a gas introducer 12, a gas exhauster 13, a transfer port 14, a heating unit 15, and a cooler 16.

The processing container 11 is a vacuum container with an internal space that is switchable to a vacuum atmosphere by evacuation. The processing container 11 is formed as a flat housing having a substantially circular shape in plan view and may accommodate a plurality of substrates W in the internal space. The substrates W may be, for example, semiconductor wafers. The processing container 11 includes a main body 111, a top plate 112, a sidewall body 113, and a bottom plate 114 (FIG. 1). The main body 111 has a cylindrical shape. The top plate 112 is removably mounted on an upper surface of the main body 111. The main body 111 and the top plate 112 are in close contact with each other in an airtight manner by a seal 115. The sidewall body 113 has a cylindrical shape and is connected to a lower surface of the main body 111 in an airtight manner. The bottom plate 114 is connected to a bottom surface of the sidewall body 113 in an airtight manner.

The gas introducer 12 includes a raw material gas nozzle 121, a reaction gas nozzle 122, and separation gas nozzles 123 and 124 (FIG. 2). The raw material gas nozzle 121, reaction gas nozzle 122, and separation gas nozzles 123 and 124 are arranged at intervals along the circumferential direction of the processing container 11 (direction indicated by arrow A in FIG. 2) above the rotary table 21 to be described later. In the illustrated example, the separation gas nozzle 123, raw material gas nozzle 121, separation gas nozzle 124, and reaction gas nozzle 122 are arranged in this order in the clockwise direction (rotation direction of the rotary table 21] from the transfer port 14. The raw material gas nozzle 121, reaction gas nozzle 122, and separation gas nozzles 123 and 124 are provided at base ends thereof with gas introduction ports 121p, 122p, 123p and 124p (FIG. 2) for introducing various gases, respectively. The gas introduction ports 121p, 122p, 123p and 124p are fixed to a sidewall of the main body 111 and protrude outward from the main body 111. The raw material gas nozzle 121, reaction gas nozzle 122, and separation gas nozzles 123 and 124 are inserted into the processing container 11 from the sidewall of the main body 111 to extend radially inward of the main body 111. The raw material gas nozzle 121, reaction gas nozzle 122, and separation gas nozzles 123 and 124 are made of, for example, quartz and are arranged parallel to the rotary table 21.

The raw material gas nozzle 121 is connected to a raw material gas source through a pipe, a flow rate controller, and others, although not illustrated. Examples of a raw material gas may include a silicon-containing gas and a metal-containing gas. The raw material gas nozzle 121 has a plurality of discharge holes (not illustrated), which are open toward the rotary table 21 and are arranged at intervals along the axial direction of the raw material gas nozzle 121. An area below the raw material gas nozzle 121 serves as a raw material gas adsorption area P1 for adsorbing the raw material gas to the substrate W.

The reaction gas nozzle 122 is connected to a reaction gas source through a pipe, a flow rate controller, and others, although not illustrated. Examples of a reaction gas may include an oxidizing gas and a nitriding gas. The reaction gas nozzle 122 has a plurality of discharge holes (not illustrated), which are open toward the rotary table 21 and are arranged at intervals along the axial direction of the reaction gas nozzle 122. An area below the reaction gas nozzle 122 serves as a reaction gas supply area P2 for oxidizing or nitriding the raw material gas adsorbed onto the substrate W in the raw material gas adsorption area P1. In the present embodiment, a process gas for processing the substrates W includes the aforementioned raw material gas and reaction gas.

Both the separation gas nozzles 123 and 124 are connected to a separation gas source through a pipe, a flow rate control valve, and others, although not illustrated. Examples of a separation gas may include an inert gas such as an argon (Ar) gas or nitrogen (N₂) gas. The separation gas nozzles 123 and 124 have a plurality of discharge holes (not illustrated), which are open toward the rotary table 21 and are arranged at intervals along the axial direction of the separation gas nozzles 123 and 124.

Further, as illustrated in FIG. 2, two convex sectors 17 are formed in the processing container 11. The convex sectors 17 are attached to an underside of the top plate 112 to protrude toward the rotary table 21, in order to constitute a separation area D in conjunction with the separation gas nozzles 123 and 124. Each convex sector 17 has an arcuately truncated fan-shape in a plan view, and is arranged such that an inner arc is connected to a protrusion 18 and an outer arc follows a sidewall of the processing container 11.

The gas exhauster 13 includes a first exhaust port 131 and a second exhaust port 132 (FIG. 2). The first exhaust port 131 is formed at the bottom of a first exhaust area E1, which is in communication with the raw material gas adsorption area P1. The second exhaust port 132 is formed at the bottom of a second exhaust area E2, which is in communication with the reaction gas supply area P2. The first exhaust port 131 and the second exhaust port 132 are connected to an exhaust device (not illustrated) through exhaust pipes (not illustrated).

The transfer port 14 is formed in the sidewall of the main body 111 (FIG. 2). The substrate W is delivered through the transfer port 14 between the rotary table 21 in the processing container 11 and a transfer device 14a outside the processing container 11. The transfer port 14 is opened or closed by a gate valve (not illustrated).

The heating unit 15 includes a fixed shaft 151, a heater support 152, and a heater 153 (FIG. 1).

The fixed shaft 151 has a cylindrical shape with the center of the processing container 11 as a central axis. The fixed shaft 151 passes through the bottom plate 114 of the processing container 11 inside a rotating shaft 23 of the rotational drive device 20 to be described later.

The heater support 152 is fixed to the top of the fixed shaft 151 and has a disc shape. The heater support 152 supports the heater 153.

The heater 153 is provided on an upper surface of the heater support 152. The heater 153 may also be provided on the main body 111, in addition to the upper surface of the heater support 152. The heater 153 generates heat upon receiving power supplied from a power supply (not illustrated), thus heating the substrate W. Further, the heater 153 may have a shield plate on an upper surface (surface opposite to the rotary table 21] thereof to prevent the heater 153 from being exposed to the process gas.

The cooler 16 includes fluid flow paths 161a to 164a, chiller units 161b to 164b, inlet pipes 161c to 164c, and outlet pipes 161d to 164d (FIG. 1). The fluid flow paths 161a to 164a are formed respectively in the main body 111, top plate 112, bottom plate 114, and heater support 152. The chiller units 161b to 164b output a temperature regulation fluid. The temperature regulation fluid output from the chiller units 161b to 164b flows through the inlet pipes 161c to 164c, fluid flow paths 161a to 164a, and outlet pipes 161d to 164d in this order for circulation. This allows for the temperature adjustment of the main body 111, top plate 112, bottom plate 114, and heater support 152. Examples of the temperature regulation fluid may include a fluorine-based fluid such as Galden (registered trademark) and water.

The rotational drive device 20 includes the rotary table 21, an accommodation box 22, the rotating shaft 23, a revolution motor 24, and an outer cylinder 25.

The rotary table 21 is provided in the processing container 11 and has a rotation center at the center of the processing container 11. For example, the rotary table 21 has a disc shape and is made of quartz. A plurality of (e.g., five) stages 211 are provided on an upper surface of the rotary table 21 along the rotation direction (circumferential direction). The rotary table 21 is connected to the accommodation box 22 via a connector 214 (FIG. 3).

Each stage 211 has a slightly larger disc shape than the substrate W, and is made of, for example, quartz. A surface 211s for disposing the substrate W is formed on an upper surface of each stage 211. Each stage 211 is connected to a rotation motor 213 through a rotation shaft 212 and is configured to be rotatable relative to the rotary table 21 (FIG. 1).

The rotation shaft 212 connects a lower surface of the stage 211 to the rotation motor 213 accommodated in the accommodation box 22, thus transmitting power of the rotation motor 213 to the stage 211. The rotation shaft 212 is configured to be rotatable about the center of the stage 211 as a rotation center. The rotation shaft 212 is provided to penetrate a ceiling 222 of the accommodation box 22 and the rotary table 21. A seal 263 is provided near a penetrating portion of the ceiling 222 of the accommodation box 22 to maintain an airtight state in the accommodation box 22. The seal 263 includes, for example, a magnetic fluid seal.

The rotation motor 213 rotates the stage 211 relative to the rotary table 21 via the rotation shaft 212, thereby rotating the substrate W around the center of the substrate W. It is desirable to apply, for example, a servo motor as the rotation motor 213.

The connector 214 connects a lower surface of the rotary table 21 to an upper surface of the accommodation box 22 (FIG. 3). The connector 214 is provided in a plural number along the circumferential direction of the rotary table 21.

The accommodation box 22 is provided below the rotary table 21 in the processing container 11. The accommodation box 22 is connected to the rotary table 21 via the connector 214 and rotates integrally with the rotary table 21. The accommodation box 22 may be configured to be raised or lowered in the processing container 11 by a lifting mechanism (not illustrated). The accommodation box 22 includes a main body 221 and a ceiling 222.

The main body 221 is formed into a concave shape in longitudinal cross-section and has a ring shape along the rotation direction of the rotary table 21 (FIG. 1).

The ceiling 222 is provided on an upper surface of the main body 221 to cover an opening of the main body 221. This allows the main body 221 and the ceiling 222 to form a rotation compartment 223 isolated from the inside of the processing container 11.

The rotation compartment 223 is formed into a rectangular shape in longitudinal cross-section and has a ring shape along the rotation direction of the rotary table 21. The rotation compartment 223 accommodates the rotation motor 213 (rotation source). A communication path 224 is formed in the main body 221 for communication between the rotation compartment 223 and the outside of the substrate processing apparatus 1. This allows the atmospheric air to be introduced into the rotation compartment 223 from the outside of the substrate processing apparatus 1, so that the inside of the rotation compartment 223 is cooled and maintained at atmospheric pressure. To rotatably arrange the rotation compartment 223, the processing container 11 has a rotation source accommodating space 19 surrounded by the sidewall body 113, bottom plate 114, and heating unit 15.

The rotating shaft 23 is fixed to a lower portion of the accommodation box 22. The rotating shaft 23 is provided to penetrate the bottom plate 114 of the processing container 11. The rotating shaft 23 transmits power of the revolution motor 24 to the rotary table 21 and the accommodation box 22, causing the rotary table 21 and the accommodation box 22 to rotate integrally. A seal 154 is provided between an outer wall of the fixed shaft 151 and an inner wall of the rotating shaft 23 of the rotational drive device 20. This allows the rotating shaft 23 to rotate relative to the fixed shaft 151 while maintaining an airtight state in the processing container 11. The seal 154 may be, for example, a magnetic fluid seal.

The outer cylinder 25 of the rotational drive device 20 is connected to a center-side lower surface portion of the bottom plate 114 of the processing container 11. The outer cylinder 25 supports the processing container 11 in conjunction with the fixed shaft 151 of the processing container 11. A seal 116 is provided between the rotating shaft 23 and the outer cylinder 25 to maintain an airtight state in the processing container 11. The seal 116 may be, for example, a magnetic fluid seal.

A passage 231 is formed inside the rotating shaft 23. The passage 231 is connected to the communication path 224 of the accommodation box 22 and functions as a fluid flow path for introducing the atmospheric air into the accommodation box 22. Further, the passage 231 also functions as a wiring duct for introducing power wires and signal wires, which are used to drive the rotation motor 213, into the accommodation box 22. For example, the passage 231 is provided in the same number as the rotation motor 213.

Further, as illustrated in FIG. 1, when the transfer device 14a (FIG. 2) loads and unloads the substrate W onto and from the stage 211, the lifter 30 raises or lowers a plurality of (three in the present embodiment) lift pins 31, thus receiving and transferring the substrate W from and to the transfer device 14a. In the substrate processing apparatus 1, the lifter 30 is installed at the vertical downward side opposite to the stage adjacent to the transfer port 14. The lifter 30 includes a plurality of (e.g., three) upper structures 40 having the respective lift pins 31 and a single lower operator 50 that simultaneously raises or lowers the plurality of lift pins 31 in the processing container 11. Further, the substrate processing apparatus 1 includes an imaging device 60 for capturing images of the substrate W transferred to the stage 211 at the vertical upward side opposite to the stage 211.

Each upper structure 40 is installed to penetrate the heater support 152 and the heater 153 and accommodates the lift pin 31 in a displaceable manner. The lower operator 50 is attached to a lower surface of the bottom plate 114 of the processing container 11. The lower operator 50 has a plurality of (three) plungers 51, which are displaced along the vertical direction to press a lower end 32 of each lift pin 31. In other words, the lifter 30 has a two-stage structure in which the plurality of lift pins 31 serving as movable members, which come into direct contact the substrate W, and the plurality of plungers 51, which indirectly raise or lower the substrate W via the lift pins 31, are separately provided in the vertical direction.

The lower operator 50 includes a case 52 and a plunger drive 53, in addition to the respective plungers 51. Further, the plunger drive 53 includes a drive source 54, a drive transmitter 55 that transmits the operation force of the drive source 54, and a movable body 56 that supports each plunger 51 and is displaced in the case 52 by the drive transmitter 55.

The case 52 is fixed to the bottom plate 114 at the lateral side of the outer cylinder 25 and is formed into a suitable shape to accommodate each component of the lower operator 50. The drive source 54 is provided at a lower portion of the case 52 and operates based on the control of the controller 90 to transmit the operation force thereof to the drive transmitter 55. The drive transmitter 55 raises or lowers the movable body 56 in the vertical direction by appropriately reducing or converting the operation force of the drive source 54. The movable body 56 extends radially outwardly (horizontally) from the drive transmitter 55 and supports a lower end portion of each plunger 51. The movable body 56 is raised or lowered along the vertical direction by the drive transmitter 55, thereby integrally displacing the respective plungers 51.

Further, the drive transmitter 55 includes an encoder (not illustrated) that measures the rotation angle of the drive source 54 (or the positions of the plungers 51), and detects the height position of the plungers 51, in other words, the height position of the lift pins 31. This allows the controller 90 to recognize the height position of the lift pins 31.

Each plunger 51 is formed in an elongated solid rod shape and is fixed to the movable body 56, thereby extending parallel to the vertical direction. A bottom plate side through-hole 114a, through which each plunger 51 passes, is formed in the bottom plate 114 at a location opposite to each plunger 51. Further, a box side through-hole 225, through which each plunger 51 passes, is formed through the accommodation box 22 at a location opposite to each plunger 51 toward the rotating shaft 23 of the accommodation box 22.

Each plunger 51 is in a standby state with an upper end portion thereof slightly protruding from the bottom plate side through-hole 114a in the non-operational state of the lift pins 31. Then, each plunger 51 is raised together with the movable body 56 and is moved in the rotation source accommodating space 19 when receiving or delivering the substrate W. Each plunger 51 passes through the side of the accommodation box 22 or the box side through-hole 225 and comes into contact with the lift pin 31 of each upper structure 40, thereby pushing up the lift pin 31.

The plurality of (three) upper structures 40 are provided at positions radially spaced apart from the rotation shaft 212 along the circumferential direction of the stage 211. Each upper structure 40 has an accommodating portion 41 for accommodating the lift pin 31, and the accommodating portion 41 supports the lift pin 31 to prevent the lift pin 31 from being removed downward in the vertical direction. The stage 211 has a plurality of (three) through-holes 211a, through which the respective lift pins 31 may pass, to correspond to the positions where the respective upper structures 40 are arranged (see also FIG. 2).

The lift pin 31 is a linearly extending cylindrical member, and a lower end thereof is located below a lower surface of the heater support 152. The plunger 51 raised by the lower operator 50 comes into contact with the lower end of the lift pin 31 to push up the lower end 32, thereby raising the entire lift pin 31. An upper end of the lift pin 31 moves vertically upward beyond the heater 153 when pressed by the plunger 51, and passes through the through-hole 211a of the stage 211 to protrude from an upper surface of the stage 211.

FIG. 4 is a side view schematically illustrating the installation state of the imaging device 60 in the processing container 11. As illustrated in FIG. 4, the imaging device 60 is installed to overlap with a window 112w formed in the top plate 112 of the processing container 11. The window 112w is made of a transparent material and is positioned adjacent to the transfer port 14 and vertically overlaps with a partial outer edge of the rotary table 21. The window 112w is provided with a sealing member (not illustrated) at a circumferential edge thereof, which closes a hole in the top plate 112 in an airtight manner.

The imaging device 60 is fixed to an upper surface of the top plate 112 and has a rectangular cylindrical housing 61 that is open downward. The housing 61 creates a darkened internal space, providing an environment suitable for imaging. Further, the imaging device 60 includes a light source 62, a reflector 63, and a camera 64 in the housing 61.

The light source 62 is arranged between the window 112w and the reflector 63 and emits light to the reflector 63 located vertically above the light source 62. The light source 62 is not particularly limited as long as it may emit light of appropriate brightness, and for example, a light emitting diode (LED) may be applied thereto.

The reflector 63 reflects the light emitted from the light source 62, directing the reflected light into the processing container 11 through the window 112w. Further, the reflector 63 has therein an aperture 630 that defines the imaging range of the camera 64.

The camera 64 is installed to the housing 61 vertically above the reflector 63 to face the window 112w below. The type of camera 64 is not particularly limited, and for example, a charge coupled device (CCD) camera may be applied thereto. The camera 64 is communicatively connected to the controller 90, captures images of the inside of the processing container 11 under the control of the controller 90, and transmits this imaging information. The imaging device 60 may include a processor (not illustrated) that image-processes the imaging information from the camera 64, and may be configured to transmit the imaging information image-processed by the processor to the controller 90.

Returning to FIG. 1, the controller 90 controls each component of the substrate processing apparatus 1. The controller 90 includes a control main body 91 and a user interface 95. The control main body 91 is a computer having one or more processors 92, a memory 93, and an input/output interface as well as a communication interface (both not illustrated). The one or more processors 92 include one or a combination of two or more of a central processing unit (CPU), graphics processing unit (GPU), application specific integrated circuit (ASIC), field-programmable gate array (FPGA), a circuit including a plurality of discrete semiconductors, and others, and executes programs stored in the memory 93. The memory 93 includes a main storage device including a semiconductor memory and others, and an auxiliary storage device including a disk, a semiconductor memory (flash memory) and others.

Further, the user interface 95 is connected to the input/output interface of the control main body 91. The user interface 95 is not particularly limited, but may include, for example, a touch panel, a monitor, a keyboard, a mouse, and others.

The controller 90 controls each component of the substrate processing apparatus 1, thereby controlling the reception of the substrate W from the transfer device 14a (FIG. 2) to each stage 211, the processing of each substrate W, the delivery of the substrate W from each stage 211 to the transfer device 14a, and others. For example, when receiving the substrate W, the controller 90 arranges the stage 211, which is appointed to dispose the substrate W, at a position adjacent to the transfer port 14 of the processing container 11. Then, after advancing the transfer device 14a from the transfer port 14, the controller 90 operates the lifter 30 to raise each lift pin 31 from the stage 211 and receive the substrate W from the transfer device 14a. After retracting the transfer device 14a, the controller 90 lowers each lift pin 31 to dispose the substrate W on the stage 211. Further, the controller 90 repeats the above operation to dispose the substrate W on each stage 211 by sequentially replacing the stage 211 adjacent to the transfer port 14 through the rotation of the rotary table 21.

During a substrate processing, the controller 90 depressurizes the processing container 11 to a predetermined internal pressure and heats each substrate W by the heating unit 15. Furthermore, the controller 90 rotates the rotary table 21 around the rotating shaft 23 while simultaneously rotating each stage 211 around the rotation shaft 212. In this state, the controller 90 supplies the raw material gas through the raw material gas nozzle 121 of the gas introducer 12, supplies the reaction gas through the reaction gas nozzle 122, and supplies the separation gas through the separation gas nozzles 123 and 124. This results in the formation of a desired film on a surface of each substrate W.

In the delivery of the substrate W after the substrate processing, the controller 90 arranges the stage 211 for delivering the substrate W at a position adjacent to the transfer port 14 of the processing container 11, and then, raises each lift pin 31 of the lifter 30 to lift the substrate W from the stage 211. Then, after the entry of the transfer device 14a, the controller 90 lowers each lift pin 31, thereby delivering the substrate W to the transfer device 14a. This allows the transfer device 14a to unload the substrate W from the processing container 11. Further, the controller 90 repeats the above operation to unload each substrate W from each stage 211 by sequentially replacing the stage 211 adjacent to the transfer port 14 through the rotation of the rotary table 21.

Then, during the loading and unloading of the substrate W, the controller 90 uses the imaging information from the camera 64 to recognize the positions of the rotary table 21, each stage 211, and the substrate W held in the transfer device 14a, and performs positioning for each.

Therefore, as illustrated in FIG. 4, the processing container 11 has a plurality of processing container side markers 11m at positions within the imaging range of the imaging device 60. Further, the rotary table 21 has a plurality of rotary table side markers 21m at appropriate positions on the outer periphery thereof. Furthermore, each stage 211 also has a plurality of stage side markers 211m at appropriate positions on the outer periphery thereof.

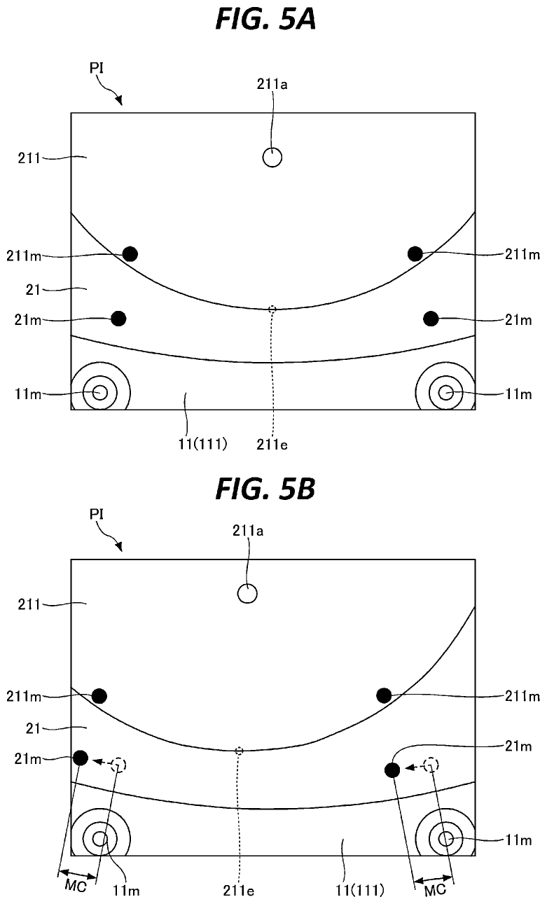

FIG. 5A is a plan view illustrating a first example of imaging information PI captured by the imaging device 60. FIG. 5B is a plan view illustrating a second example of the imaging information PI captured by the imaging device 60. As illustrated in FIG. 5A, each processing container side marker 11m, each rotary table side marker 21m, and each stage side marker 211m are formed in a circular shape, respectively. Further, as described above, the imaging range of the imaging information PI is defined by the reflector 63 of the imaging device 60, and is set to a size that allows each marker to be captured.

For example, the imaging range of the imaging device 60 is set such that the imaging information PI includes a plurality of (e.g., two in FIG. 5A) processing container side markers 11m of the processing container 11. As an example, the two processing container side markers 11m are arranged respectively toward both sides in the exact width direction (e.g., left-and-right direction in FIG. 5A) within the imaging range and are positioned at the same distance from the edges of the imaging range in the left-and-right direction. The processing container side markers 11m may adopt an appropriate configuration formed on the processing container 11, and, for example, may adopt fasteners for fastening the main body 111 and the sidewall body 113.

Meanwhile, a plurality of rotary table side markers 21m are formed at positions adjacent to the outer edge of the rotary table 21. The respective rotary table side markers 21m are positioned to correspond to the respective stages 211. For example, a pair of (two) rotary table side markers 21m are formed radially outside a corresponding one stage 211. Further, the pair of rotary table side markers 21m are positioned symmetrically with respect to an outer edge position 211e of each stage 211, which is at the maximum distance from the center of the rotary table 21, and are spaced apart from the outer edge position 211e at the same distance.

As illustrated in FIG. 5A, when imaging is made so that the outer edge position 211e of the stage 211 is positioned at the width direction center of the imaging information PI, the pair of rotary table side markers 21m are positioned at the same distance from the edges of the imaging range in the left-and-right direction. In this case, each of the pair of rotary table side markers 21m is positioned at the same distance from each adjacent processing container side marker 11m. In other words, the substrate processing apparatus 1 may calculate the respective relative positions of the pair of rotary table side markers 21m with respect to the pair of processing container side markers 11m using the imaging information PI. Then, the substrate processing apparatus 1 may recognize a misalignment amount in the circumferential position of the rotary table 21 when the stage 211 is positioned at the transfer port 14 through the rotation of the rotary table 21 based on the relative positions between the processing container side markers 11m and the rotary table side markers 21m.

As an example, it is assumed that the controller 90 has acquired the imaging information PI illustrated in FIG. 5B. In this case, the controller 90 may recognize that each rotary table side marker 21m is shifted clockwise by a misalignment amount MC with respect to each processing container side marker 11m by extracting each rotary table side marker 21m and each processing container side marker 11m from the imaging information PI. Then, the controller 90 may rotate the rotary table 21 counterclockwise based on the calculated misalignment amount MC and may further adjust the rotation angle (correction amount), thereby positioning each rotary table side marker 21m as illustrated in FIG. 5A.

Then, each stage 211 has a plurality of (two in FIG. 5A) stage side markers 211m on the outer periphery thereof adjacent to the outer edge of the stage 211. The two stage side markers 211m are set at positions where the angle between intersecting virtual lines drawn between the respective stage side markers 211m and the center of the stage 211 is 60 degrees. The stage 211 is configured to have two stage side markers 211m positioned at 60-degree intervals along the circumferential direction of the outer periphery, with no markers in the remaining circumferential direction (300 degrees) of the outer periphery.

Here, the imaging device 60 adjusts the imaging range thereof to capture images of the outer periphery of the stage 211 within a range of about 61 to 70 degrees when the outer edge position 211e of the stage 211 is located at the width direction center of the imaging information PI. Accordingly, the two stage side markers 211m may be included in the imaging information PI when the outer edge position 211e of the stage 211 is located at the width direction center of the imaging information PI. However, since the outer periphery of the stage 211 is provided with the two stage side markers 211m at 60-degree intervals, each stage side marker 211m is not captured depending on the rotational position of the stage 211.

The controller 90 is configured to repeat capturing images with the imaging device 60 while rotating the stage 211, which is opposite to the imaging device 60, by 60-degree increments, up to six times. Thus, while repeating the 60-degree rotation of the stage 211 six times, the stage side marker 211m may be included in the imaging information PI. Then, the substrate processing apparatus 1 sets each lift pin 31 to be exactly aligned with each through-hole 211a of the stage 211 at the position where the two stage side markers 211m are included in the imaging information PI. By aligning each lift pin 31 with each through-hole 211a, it is possible to raise the lift pin 31 above the surface 211s of the stage 211.

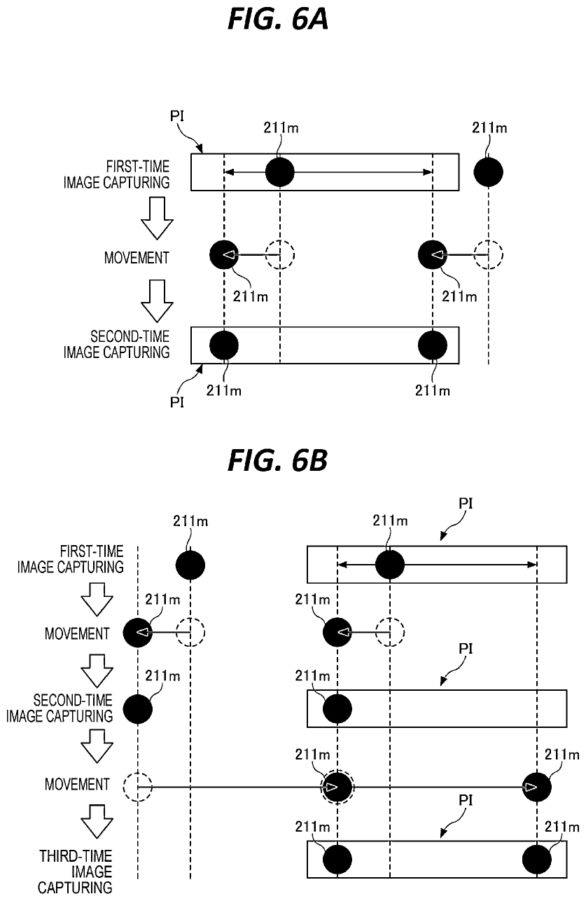

Accordingly, the controller 90 is configured to control the rotation angle and rotation direction of the stage 211 so that the two stage side markers 211m are included in the imaging information PI. Hereinafter, the control to ensure that the two stage side markers 211m are included in the imaging information PI will be described with reference to FIGS. 6A and 6B. FIG. 6A is a first explanatory diagram illustrating an example in which the two stage side markers 211m are captured by clockwise rotation. FIG. 6B is a second explanatory diagram illustrating an example in which the two stage side markers 211m are captured by clockwise rotation and counterclockwise rotation.

In the following, a pattern in which one stage side marker 211m is included in the imaging information PI, as illustrated in FIGS. 6A and 6B, is assumed. This is because the control to rotate the stage 211 by 60 degrees described above will be performed when there is no stage side marker 211m in the imaging information PI.

Further, as illustrated in FIG. 6A, it is assumed that one of the two stage side markers 211m (on the left side) is included in the imaging information PI. In this case, the controller 90 may not determine where the other stage side marker 211m is located based solely on the imaging information PI. Therefore, the controller 90 stipulates to rotate the stage 211 in a first direction (e.g., clockwise) when one stage side marker 211m is captured. Further, the controller 90 sets a movement amount (rotation angle) of the stage 211 at this time so that the captured stage side marker 211m is adjacent to the left edge of the imaging information PI based on the position of the stage side marker 211m within the imaging information PI.

Then, the controller 90 rotates the stage 211 clockwise by the set movement amount. Thus, when another stage side marker 211m has been on the right side, the another stage side marker is shifted to a position within the imaging range of the imaging device 60. Accordingly, the controller 90 may obtain an image in which the two stage side markers 211m are included in the imaging information PI by capturing images a second time with the imaging device 60.

Conversely, as illustrated in of FIG. 6B, it is assumed that the right stage side marker 211m among the two stage side markers 211m is included in the imaging information PI. In this case as well, the controller 90 rotates the stage 211 in the first direction (e.g., clockwise). Further the controller 90 sets a movement amount (rotation angle) of the stage 211 at this time so that the captured stage side marker 211m is adjacent to the left edge of the imaging information, similar to the above.

Then, the controller 90 rotates the stage 211 clockwise by the set movement amount. Here, when the right stage side marker 211m was included in the imaging information PI, only one stage side marker 211m will be included in the imaging information PI, which is obtained by capturing images a second time with the imaging device 60, even after rotation by the set movement amount. However, based on this result, the controller 90 may recognize that the stage side marker 211m included in the imaging information PI was on the right side.

Thus, next, the controller 90 rotates the stage 211 in a second direction (e.g., counterclockwise) opposite to the first direction. Further, the controller 90 sets a movement amount of the stage 211 at this time so that the captured stage side marker 211m is adjacent to the right edge of the imaging information PI. Then, the controller 90 rotates the stage 211 counterclockwise by the set movement amount. Thus, the left stage side marker 211m is shifted to a position within the imaging range of the imaging device 60. The controller 90 may obtain an image in which the two stage side markers 211m are included in the imaging information PI by capturing images a third time with the imaging device 60.

Then, when there are the two stage side markers 211m in the imaging information PI, it may be considered that a misalignment amount of each stage side marker 211m with respect to the imaging information PI is minimal (or there is no misalignment). When there is a slight misalignment between the two stage side markers 211m in the imaging information PI, a correction amount for correcting the position of the stage 211 may be calculated based on the position of each stage side marker 211m in the imaging information PI. For example, the controller 90 may obtain the correction amount of the stage 211 based on the distance from the edges of the imaging information PI in the left-and-right direction to the respective stage side markers 211m. Alternatively, the controller 90 may obtain the correction amount of the stage 211 based on the relative position of the stage side marker 211m with respect to the rotary table side marker 21m included in the imaging information PI. This allows the position of the stage 211 to be precisely aligned with the rotary table side marker 21m.

### [Method of Disposing Substrate W]

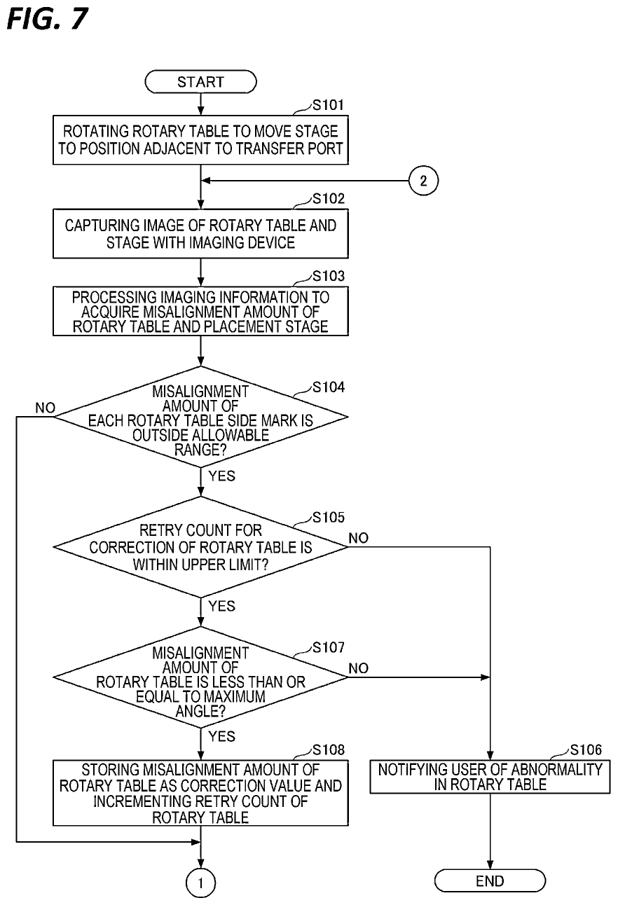

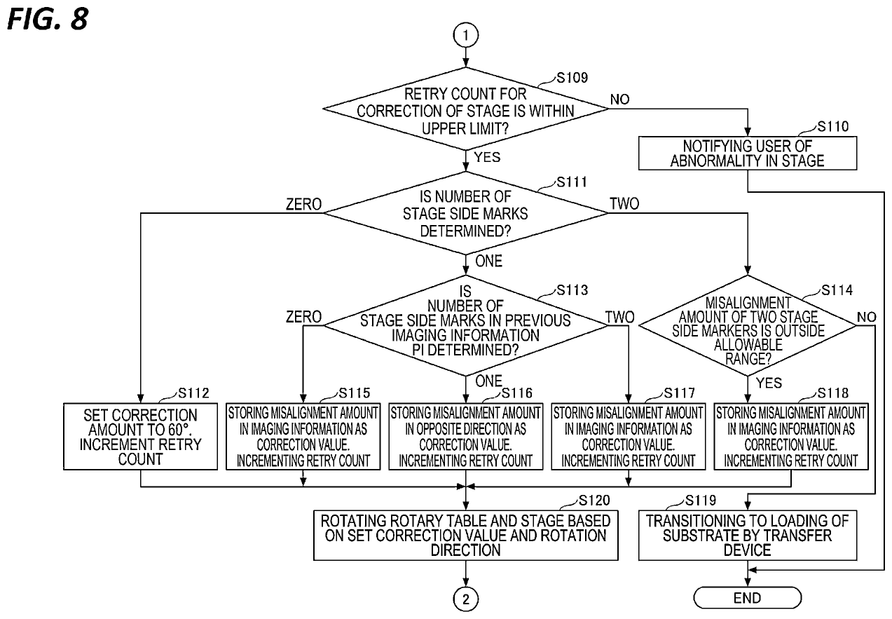

The substrate processing apparatus 1 according to the embodiment is basically configured as described above, and hereinafter, a method of disposing the substrate W during loading of the substrate W will be described with reference to FIGS. 7 and 8. FIG. 7 is a first flowchart illustrating the correction of the position of the rotary table 21 and the correction of the position of the stage 211. FIG. 8 is a second flowchart illustrating the correction of the position of the rotary table 21 and the correction of the position of the stage 211.

In the loading of the substrate W, the substrate processing apparatus 1 performs the processing flow of steps S101 to S120 in FIGS. 7 and 8 under the control of the controller 90.

Specifically, when the controller 90 starts the method of disposing the substrate W, it rotates the rotary table 21 to move the stage 211, on which the substrate W is to be disposed, to a position adjacent to the transfer port 14 (step S101). At this time, the controller 90 rotates the rotary table 21 by a rotation angle stored in advance. For example, in a configuration with five stages 211 as illustrated in FIG. 2, when replacing the stage 211 adjacent to the transfer port 14 with the next stage 211, the controller 90 rotates the rotary table 21 by a rotation angle of 72 degrees. Thus, the stage 211, on which the substrate W is to be disposed, is moved to a position adjacent to the transfer port 14.

Next, the controller 90 captures images of the rotary table 21 and the stage 211 with the imaging device 60 (step S102).

Then, after acquiring the imaging information PI from the imaging device 60, the controller 90 processes the imaging information PI (step S103). Further, in addition to processing the imaging information PI, the controller 90 also acquires (extracts or calculates) misalignment amount information for the rotary table 21 as well as misalignment amount information for the stage 211 based on the imaging information PI.

Here, the substrate processing apparatus 1 has a possibility of disturbances such as eccentricity or thermal effects affecting the rotary table 21 or each stage 211 due to a substrate processing and other factors. For example, when the position of the rotary table 21 or each stage 211 is misaligned due to thermal effects, the substrate W may not be disposed at the correct position, and in some cases, the substrate W may be scratched, potentially generating particles.

The misalignment amount information for the rotary table 21 obtained from the imaging information PI includes a misalignment amount in the rotation direction and a misalignment amount in the horizontal direction (X-axis and Y-axis directions) of the rotary table 21. Further, the misalignment amount information for the stage 211 includes the number of stage side markers 211m and a misalignment amount in the horizontal direction (X-axis and Y-axis directions) of one or two stage side markers 211m.

After the processing of the imaging information is completed, the controller 90 first determines whether correction for the positioning of the rotary table 21 is necessary based on the misalignment amount of the rotary table 21. In this case, the controller 90 first determines whether the misalignment amount of each rotary table side marker 21m included in the imaging information PI is outside the allowable range (step S104). When the misalignment amount of the rotary table side marker 21m is within the allowable range (step S104: NO), it can be said that the rotation of the rotary table 21 has been completed almost exactly and the stage 211 is positioned adjacent to the transfer port 14. Therefore, the positioning of the rotary table 21 may be completed as it is, and the controller 90 proceeds to step S109.

Meanwhile, when the misalignment amount of the rotary table side marker 21m is outside the allowable range (step S104: YES), the controller 90 proceeds to step S105. In step S105, the controller 90 determines whether a retry count, which refers to the number of times the rotation angle of the rotary table 21 has been corrected, is within the upper limit. When the retry count exceeds the upper limit (step S105: NO), it means that the positioning of the rotary table 21 may not be performed correctly even after retrying the correction of the position of the rotary table 21. In this case, it may be assumed that any kind of abnormality such as a malfunction or significant distortion has occurred in the rotary table 21, so that the controller 90 proceeds to step S106 and notifies the user of the abnormality in the rotary table 21 via the user interface 95.

Further, when the retry count is within the upper limit (step S105: YES), the controller 90 proceeds to step S107. In step S107, the controller 90 determines whether the misalignment amount of the rotary table 21 acquired in step S103 is less than or equal to a set threshold (maximum angle). When the misalignment amount of the rotary table 21 exceeds the threshold (step S107: NO), it means that the rotary table 21 has been misaligned to an extent that may not normally occur when the rotary table 21 was rotated in step S101. In this case, it may again be assumed that any kind of abnormality such as a malfunction or significant distortion has occurred in the rotary table 21. Therefore, the controller 90 proceeds to step S106 and notifies the user of the abnormality in the rotary table 21 via the user interface 95.

Meanwhile, when the misalignment amount of the rotary table 21 is less than or equal to the threshold (step S107: YES), the controller 90 proceeds to step S108. In step S108, the controller 90 stores the misalignment amount of the rotary table 21 acquired in step S103 in the memory 93 as a correction amount for the next rotation of the rotary table 21. Further, at this time, the controller 90 increments the retry count for the rotary table 21 by one and stores the incremented retry count.

Through the above processing flow, the necessity of correction for the positioning of the rotary table 21 and the preparation for correction are made. However, the controller 90 does not perform an operation to correct the position of the rotary table 21 at this time. Subsequently, the controller 90 sets the necessity of correction and correction details required when performing the correction for the stage 211 included in the imaging information PI, thereby performing the correction of the rotary table 21 and the correction of the stage 211 simultaneously later.

Regarding the stage 211, the controller 90 first determines whether a retry count, which refers to the number of times the rotation angle of the stage 211 has been corrected, is within the upper limit (step S109). When the retry count exceeds the upper limit (step S109: NO), it means that the positioning of the stage 211 may not be performed correctly even after retrying the correction of the rotation angle of the stage 211. In this case, it may be assumed that any kind of abnormality such as a malfunction or distortion has occurred in the stage 211, so that the controller 90 proceeds to step S110 and notifies the user of the abnormality in the stage 211 via the user interface 95.

Next, the controller 90 determines the number of stage side markers 211m included in the imaging information PI (step S111). This is because the rotation angle of the stage 211 varies depending on the number of stage side markers 211m in the imaging information PI, as described above.

When it is determined in step S111 that the number of stage side markers 211m is zero, the controller 90 sets a correction value for rotating the stage 211 to 60 degrees, and further increments the retry count by one and stores the incremented retry count (step S112). Meanwhile, the controller 90 proceeds to step S113 when it is determined in step S111 that the number of stage side markers 211m is 1, or proceeds to step S114 when it is determined in step S111 that the number of stage side markers 211m is 2.

Then, in step S113, the controller 90 determines the number of stage side markers 211m in the previous imaging information PI. When there were two stage side markers 211m in the previous imaging information PI, it means that the number of stage side markers 211m decreased due to the retry rotation. Therefore, the controller 90 sets the rotation direction of the stage 211 to the opposite direction of the retry rotation and stores the misalignment amount of the stage 211 acquired in step S103 in the memory 93 as a correction value (step S115). Further, at this time, the controller 90 increments the retry count for the stage 211 by one and stores the incremented retry count.

Further, in step S113, when there was one stage side marker 211m in the previous imaging information PI, it means that the number of stage side markers 211m did not increase despite the retry rotation. This pattern corresponds to the result of the first movement in FIG. 6B. Accordingly, the controller 90 sets the rotation direction of the stage 211 to the opposite direction of the retry rotation and stores a misalignment amount for the stage side marker 211m to move to the opposite edge of the imaging information PI in the memory 93 as a correction value (step S116). Further, at this time, the controller 90 increments the retry count for the stage 211 by one and stores the incremented retry count.

In step S113, when the number of stage side markers 211m in the previous imaging information PI was zero, it means that one stage side marker 211m was captured by a 60-degree rotation. This pattern corresponds to the initial state in FIG. 6A. Accordingly, the controller 90 sets the rotation direction of the stage 211 to a preset direction and stores the misalignment amount of the stage 211 acquired in step S103 in the memory 93 as a correction value (step S117). Further, at this time, the controller 90 increments the retry count for the stage 211 by one and stores the incremented retry count.

Meanwhile, in step S114, the controller 90 determines whether a misalignment amount of the two stage side markers 211m included in the imaging information PI is outside the allowable range. When the misalignment amount of the two stage side markers 211m is outside the allowable range (step S114: YES), it means that the rotation angle of the stage 211 is slightly misaligned. Therefore, the controller 90 stores the misalignment amount of the stage 211 acquired in step S103 in the memory 93 as a correction value (step S118). Further, at this time, the controller 90 increments the retry count for the stage 211 by one and stores the incremented retry count.

Conversely, when the misalignment amount of the two stage side markers 211m is within the allowable range (step S114: NO), it can be said that the rotation of the stage 211 has been completed almost exactly and each lift pin 31 is aligned with each through-hole 211a. Therefore, the positioning of the stage 211 may be completed, and the controller 90 proceeds to step S119.

When the controller 90 proceeds to step S119, it means that the positioning of the rotary table 21 and the stage 211 has been completed. Therefore, the controller 90 completes the positioning of the stage 211, on which the substrate W is to be disposed, and transitions to the loading of the substrate W by the transfer device 14a.

After performing any one of steps S112 and S115 to S118, the controller 90 proceeds to step S120. In step S120, the controller 90 rotates the rotary table 21 based on the set correction value and rotation direction for the rotary table 21, and simultaneously rotates the stage 211 based on the set correction value and rotation direction for the stage 211. In other words, the substrate processing apparatus 1 may prevent the loss of time caused by separate corrections by collectively rotating the rotary table 21 and the stage 211. After step S120, the controller 90 returns to step S102 to perform capturing images with the imaging device 60, and repeats the following same processing flow.

As described above, the method of disposing the substrate W enables the rapid positioning of both the revolving rotary table 21 and the rotating stage 211 by using the rotary table side markers 21m and the stage side markers 211m. Even when there is positional misalignment in the rotary table 21 or the stage 211 due to disturbances such as eccentricity or thermal effects, the substrate W may be disposed on the stage 211 with high precision through re-correction of the positions of the rotary table 21 and the stage 211. As a result, the substrate processing apparatus 1 may prevent the generation of particles caused by the substrate W rubbing during rotation of the stage 211.

The substrate processing apparatus 1 and the method of disposing the substrate W are not limited to the above-described embodiments and may take various modifications. For example, each processing container side marker 11m, each rotary table side marker 21m, and each stage side marker 211m are not limited to being circular in plan view, but may have various other shapes. For example, each processing container side marker 11m, each rotary table side marker 21m, and each stage side marker 211m may have a polygonal shape such as a triangular shape or a square shape. Further, the rotary table side marker 21m and the stage side marker 211m may be formed as cutouts in the edge of a disc.

Furthermore, each of the processing container side marker 11m, rotary table side marker 21m, and stage side marker 211m is not limited to being provided in a pair (of two) but may be provided as one or three or more. For example, each of the processing container side marker 11m, rotary table side marker 21m, and stage side marker 211m may be provided to exhibit a triangular shape, and the position of each marker may be corrected so that the vertices of the triangular shape are aligned in the radial direction. Even in this case, the substrate processing apparatus 1 may efficiently perform the positioning of the rotary table 21 and the stage 211.

The technical ideas and effects of the present disclosure described in the above embodiments will be described below.

A first aspect of the present disclosure is a substrate processing apparatus 1 including a processing container 11, a rotary table 21 rotatably provided in the processing container 11, a stage 211 having a rotation center positioned away from a rotation center of the rotary table 21, the stage 211 being rotatable relative to the rotary table 21, an imaging device 60 provided in the processing container 11 and configured to capture an image of the rotary table 21 and the stage 211, and a controller 90 configured to process imaging information PI from the imaging device 60 and to control rotation of the rotary table 21 and operation of the stage 211. The rotary table 21 includes a rotary table side marker 21m capable of being positioned within an imaging range of the imaging device 60 by rotation of the rotary table 21. The stage 211 includes a stage side marker 211m capable of being positioned within the imaging range of the imaging device 60 by rotation of the stage 21. The controller 90 is configured to recognize a circumferential position of the rotary table 21 based on the rotary table side marker 21m included in the imaging information PI, and correct a position of the rotary table 21 when the rotary table side marker 21m is misaligned, and to recognize a circumferential position of the stage 211 based on the stage side marker 211m included in the imaging information PI, and correct a position of the stage 211 when the stage side marker 211m is misaligned.

According to the above, the substrate processing apparatus 1 may position the stage 211, which rotates relative to the rotary table 21, with high precision by using the stage side marker 211m capable of being positioned within the imaging range of the imaging device 60. This allows for correction of the position of the stage 211 using the imaging information PI from the imaging device 60, for example, even when disturbances such as eccentricity or thermal effects affecting on the rotary table 21 cause misalignment of the rotary table 21 or the stage 211. As a result, it becomes possible to precisely dispose the substrate W on the stage 211, thereby significantly reducing the generation of particles caused by rubbing of the substrate W and other factors.

Further, the controller 90 is configured to set both a correction direction and correction amount for the position of the rotary table 21 and a correction direction and correction amount for the stage 211 based on a single piece of the imaging information PI captured by the imaging device 60. Thus, the substrate processing apparatus 1 may reduce the loss of time associated with positioning the stage 211 after positioning the rotary table 21, thereby improving operational efficiency. As a result, it becomes possible to mitigate thermal effects on the substrate W that is loaded in advance.

Further, the processing container 11 has a processing container side marker 11m formed within the imaging range of the imaging device 60, and the controller 90 is configured to recognize the circumferential position of the rotary table 21 based on a relative position between the processing container side marker 11m and the rotary table side marker 21m included in the imaging information PI. Thus, the substrate processing apparatus 1 may correct the position of the rotary table 21 with an improved accuracy.

Further, the controller 90 is configured to rotate the stage 211 by a set angle to perform capturing an image with the imaging device 60 when the stage side mark 211m is not included in the imaging information PI. Thus, the substrate processing apparatus 1 may ensure that the stage side marker 211m is included in the imaging information PI even when there is no stage side marker 211m.

Further, the stage side marker 211m is formed in a pair on an outer periphery of the stage 211, and the controller 90 rotates the stage 211 so that the pair of stage side markers 211m are positioned within the imaging range of the imaging device 60. Thus, the substrate processing apparatus 1 may easily correct the position of the stage 211.

Further, the controller 90 is configured to rotate the stage 211 in a first direction when one of the stage side markers 211m in the pair is included in the imaging information PI, to complete correction of the position of the stage 211 when both the stage side markers 211m in the pair are included in the imaging information PI captured after rotation in the first direction, and to rotate the stage 211 in a second direction opposite to the first direction to position the pair of stage side markers 211m within the imaging range of the imaging device 60 when only one of the stage side markers 211m in the pair is included in the imaging information PI captured after rotation in the first direction. Thus, the substrate processing apparatus 1 may precisely correct the position of the stage 211.

Further, the controller 90 is configured to calculate a correction amount for correction of the position of the stage 211 based on a position of the stage side marker 211m in the imaging information PI. Thus, the controller 90 may easily obtain the misalignment amount of the stage 211.

Further, the controller 90 is configured to calculate a correction amount for correction of the position of the stage 211 based on a position of the stage side marker 211m with respect to the rotary table side marker 21m included in the imaging information PI. Thus, the controller may further precisely obtain the misalignment amount of the stage 211.

Further, a second aspect of the present disclosure is a substrate disposing method including providing a substrate processing apparatus 1 including a processing container 11, a rotary table 21 rotatably provided in the processing container 11, the stage 211 having a rotation center positioned away from a rotation center of the rotary table 21, the stage 211 being rotatable relative to the rotary table 21, and an imaging device 60 provided in the processing container 11 and configured to capture an image of the rotary table 21 and the stage 211, in which the rotary table 21 has a rotary table side marker 211m capable of being positioned within an imaging range of the imaging device 60 by rotation of the rotary table 21, in which the stage 211 has a stage side marker 211m capable of being positioned within the imaging range of the imaging device 60 by rotation of the stage 211; recognizing a circumferential position of the rotary table 21 based on the rotary table side marker 21m included in the imaging information PI of the imaging device 60, and correcting a position of the rotary table 21 when the rotary table side marker 21m is misaligned; and recognizing a circumferential position of the stage 211 based on the stage side marker 211m included in the imaging information PI, and correcting a position of the stage 211 when the stage side marker 211m is misaligned. Even in this case, the method of disposing the substrate W allows for positioning the stage 211, which rotates relative to the rotary table 21, with an improved accuracy.

According to one aspect, it is possible to position a stage, which rotates relative to a rotary table, with an improved accuracy.

From the foregoing content, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate processing apparatus comprising:
a processing container;
a rotary table rotatably provided in the processing container;
a stage having a rotation center positioned away from a rotation center of the rotary table, the stage being rotatable relative to the rotary table;
a camera provided in the processing container and configured to capture an image of the rotary table and the stage; and
a controller configured to process imaging information from the camera, and to control rotation of the rotary table and operation of the stage,
wherein the rotary table includes a rotary table side marker capable of being positioned within an imaging range of the camera by rotation of the rotary table, the stage includes a stage side marker capable of being positioned within the imaging range of the camera by rotation of the stage,
the controller is configured to:
recognize a circumferential position of the rotary table based on the rotary table side marker included in the imaging information, and correct a position of the rotary table when the rotary table side marker is misaligned; and
recognize a circumferential position of the stage based on the stage side marker included in the imaging information, and correct a position of the stage when the stage side marker is misaligned.

2. The substrate processing apparatus according to claim 1, wherein the controller is configured to set both a correction direction and correction amount for the position of the rotary table and a correction direction and correction amount for the stage based on a single piece of the imaging information captured by the camera.

3. The substrate processing apparatus according to claim 1, wherein the processing container has a processing container side marker formed within the imaging range of the camera, and
the controller is configured to recognize the circumferential position of the rotary table based on a relative position between the processing container side marker and the rotary table side marker included in the imaging information.

4. The substrate processing apparatus according to claim 1, wherein the controller is configured to rotate the stage by a set angle, thereby capturing an image with the camera, when the stage side mark is not included in the imaging information.

5. The substrate processing apparatus according to claim 1, wherein a pair of stage side markers is formed on an outer periphery of the stage, and
the controller rotates the stage such that the pair of stage side markers are positioned within the imaging range of the camera.

6. The substrate processing apparatus according to claim 5, wherein the controller is configured to:
rotate the stage in a first direction when one of the stage side markers in the pair is included in the imaging information;
end correction of the position of the stage when both of the stage side markers in the pair are included in the imaging information captured after rotation in the first direction; and
rotate the stage in a second direction opposite to the first direction to position the pair of stage side markers within the imaging range of the imaging device when only one of the stage side markers in the pair is included in the imaging information captured after rotation in the first direction.

7. The substrate processing apparatus according to claim 5, wherein the controller is configured to calculate a correction amount for correction of the position of the stage based on positions of the stage side markers in the imaging information.

8. The substrate processing apparatus according to claim 5, wherein the controller is configured to calculate a correction amount for correcting the position of the stage based on positions of the stage side markers with respect to the rotary table side marker included in the imaging information.

9. A substrate disposing method comprising:
providing a substrate processing apparatus including:
a processing container;
a rotary table rotatably provided in the processing container;
a stage having a rotation center positioned away from a rotation center of the rotary table, the stage being rotatable relative to the rotary table; and
a camera provided in the processing container, and configured to capture an image of the rotary table and the stage,
wherein the rotary table includes a rotary table side marker capable of being positioned within an imaging range of the camera by rotation of the rotary table, and
the stage includes a stage side marker capable of being positioned within the imaging range of the camera by rotation of the stage,
recognizing a circumferential position of the rotary table based on the rotary table side marker included in the imaging information of the imaging device, and correcting a position of the rotary table when the rotary table side marker is misaligned; and
recognizing a circumferential position of the stage based on the stage side marker included in the imaging information, and correcting a position of the stage when the stage side marker is misaligned.
